(19) United States
(12) Patent Application Publication
(10) Pub. No.: US 2007/0239976 A1
(43) Pub. Date: Oct. 11, 2007

(54) Message displaying system and method

(75) Inventor: Kun-Hung Huang, Taipei (TW)

Correspondence Address: EDWARDS ANGELL PALMER & DODGE LLP, P.O. BOX 55874, BOSTON, MA, 02205, US

(73) Assignee: Inventec Corporation, Taipei (TW)

(21) Appl. No.: 11/391,787

(22) Filed: Mar. 28, 2006

(51) Int. Cl. G06F 15/177; G01R 31/00; G08B 21/00

(52) U.S. Cl. 713/1; 340/679; 324/500

(57) ABSTRACT

A message displaying system and method is applicable to an electronic device having a BIOS and a display unit that executes a POST process. The message displaying method includes establishing a message table according to a plurality of message codes output by the BIOS when the electronic device is executing the POST process and a plurality of message code messages corresponding to the message codes, reading message codes output by the BIOS when the electronic device is executing the POST process, reading one of the message code messages stored in the message table and corresponding to the read message code, and displaying the read message code and its corresponding message code message on the display unit of the electronic device. Thereby, a user of the electronic device can know the status of every stage of the POST process along with debugging information.

### BACKGROUND OF THE INVENTION

1. Field of the Invention

The present invention relates to message displaying techniques and, more particularly to a message displaying system and method applicable to an electronic device having a basic input/output system (BIOS) that executes a power-on self test (POST) process.

2. Description of Related Arts

In general, modern data processing devices such as computers utilize a basic input/output system (BIOS) modules. The BIOS comprises a basic system-setting program. With the system-setting program, a user can therefore configure a computer according to specific demands, controlling the computer to execute specific functions. When the computer is powered on, a central processing unit (CPU) of the computer controls the BIOS to execute a power-on self test (POST) process, which includes a memory capacity and type test, a reset test, a keyboard test, an interrupt test, and a display test.

When the computer executes the POST process, corresponding POST codes will be displayed on a computer display. If a problem is encountered during the POST process, the BIOS will cease executing. Generally, a professional with expertise in debugging is required to solve such problems by interpreting the POST codes. Another approach to indicating problems is to install a POST code light emitting diode (LED) on the main board and perceive the light emitted by the POST code LED. However, the debugging personnel has to open the case of the computer to perceive the light emitted by the POST code LED and discover the problem. Moreover, the manufacture has to spend additional money on the LED.

In order to solve these problems, some manufactures provide a debugging card, which is installed with an LED and is capable of differentiating problem types of the computer. The location where the debug card is installed in the computer depends on a setting in the BIOS. For example, if the BIOS transfers debug codes to port 378, a printer port for a printer, the debug card is inserted into the printer port. Therefore, when a problem occurs, an LED on the debug card corresponding to the debug code will emit light. However, such a solution requires expenditure of additional money to buy the debug card. Moreover, the LED on the debug card cannot provide further information about the problem.

In summary, it is desirable to provide a solution that is capable of displaying the meanings represented by the POST code directly on the computer display to allow a user to know the execution status at every stage of the POST process.

### SUMMARY OF THE INVENTION

In view of the above-mentioned problems of the prior art, it is a primary objective of the present invention to provide a message displaying system and method that displays the operational status of an electronic device using complete messages associated with message codes. Thereby, a user of the electronic device is capable of knowing the status at every stage of the POST process and can perform debugging according to the message code messages if the electronic device encounters any problems when executing the POST process.

It is another objective of the present invention to provide a message displaying system and method that doesn't require installation of any additional hardware.

To achieve the above-mentioned and other objectives, a message displaying system is provided according to the present invention. The message displaying system is applicable to an electronic device having a basic input/output system (BIOS) and a display unit, wherein the electronic device executes a power-on self test (POST) process. The message displaying system comprises a storage unit for storing a plurality of message codes output by the BIOS when the electronic device is executing the POST process, the storage unit having a message table comprising a plurality of message code messages corresponding to the message codes; and a host module for reading message codes output by the BIOS when the electronic device is executing the POST process, reading the message code messages stored in the message table of the storage unit corresponding to the read message codes, and displaying the read message codes and the message code messages on the display unit of the electronic device.

According to the preferred embodiment, the message codes are POST codes; the message table further includes storage capacity information for the message codes and the message code messages; the host module includes a message code reading unit for reading message codes output by the BIOS when the electronic device is executing the POST process, a message code content reading unit for reading the message code messages stored in the message table of the storage unit corresponding to the read message codes, and a control unit for displaying the message codes read by the message code reading unit and the message code messages read by the message code content reading unit, such information being displayed on a display unit connected with the control unit.

In accordance with the above message displaying system, the present invention further disclosed a message displaying method applicable to an electronic device having a BIOS and a display unit, wherein the electronic device executes a POST process. The message displaying method includes establishing a message table according to a plurality of message codes output by the BIOS when the electronic device is executing the POST process and a plurality of message code messages corresponding to the message codes, reading message codes output by the BIOS when the electronic device is executing the POST process, reading the message code messages stored in the message table corresponding to the read message code, and displaying the read message codes and the corresponding message code messages on the display unit of the electronic device.

According to the preferred embodiment, the message table is stored in a storage unit; the message codes are POST codes; the message table further includes storage capacity information for the message codes and the message code messages.

In contrast to the prior art, the message displaying system and method of the present invention are designed to achieve the primary and other objectives by the interacting operations of the storage unit and the host module.

### BRIEF DESCRIPTIONS OF THE DRAWINGS

FIG. 1 is a block diagram of an electronic device having the message displaying system of the preferred embodiment according to the present invention; and

FIG. 2 is a flow chart of a message displaying method corresponding to the message displaying system shown in FIG. 1.

### DETAILED DESCRIPTIONS OF PREFERRED EMBODIMENT

The following illustrative embodiment is provided to illustrate advantages and effects of present invention, other advantages and effects can be understood by those in the art after reading the disclosure of this specification. The present invention can also be performed or applied by differing embodiments. The details of the specification are given on the basis of a particular application, and numerous modifications and variations can be devised without departing from the spirit of the present invention.

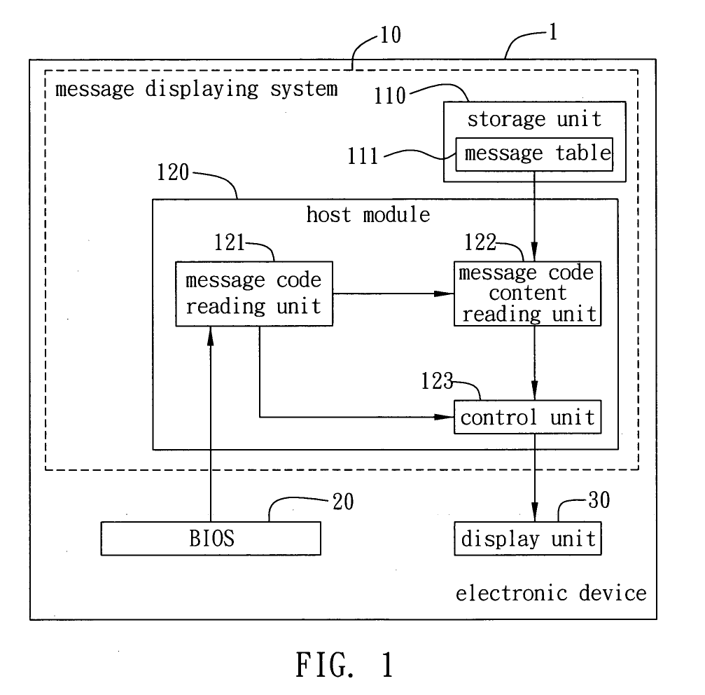

FIG. 1 is a block diagram of an electronic device 1 having a message displaying system 10 of the preferred embodiment according to the present invention. The message displaying system 10 of the present invention is applicable to the electronic device 1, which has a basic input/output system (BIOS) 20 that executes a power-on self test (POST). The electronic device 1 comprises a display unit 30. According to the present invention, the electronic device 1 is a desktop computer, a notebook computer, a pocket personal computer, a server, or a super computer, and the display unit 30 is a display.

The message displaying system 10 comprises a storage unit 110 and a host module 120, both of which will be described in detail in the following paragraphs.

The storage unit 110 has a message table 111 having a plurality of message codes (POST codes) output by the BIOS 20 when the electronic device 1 is executing the POST process, and a plurality of message code messages corresponding to the message codes. According to the present invention, the storage unit 110 is a memory. The message table 111 further comprises storage capacity information corresponding to the message codes and the message code messages for improving the efficiency of the host module 120 to retrieve corresponding message code messages.

The host module 120 is used to read the message codes output by the BIOS 20, read message code messages stored in the message table 111 in accordance with the read message codes, and display the read message codes and message code messages on the display unit 30 of the electronic device 1. In practice, the host module 120 first has the message code reading unit 121 read a message code output by the BIOS 20 when the electronic device 1 is executing the POST process. The host module 120 then has the message code content reading unit 122 read the corresponding message code message stored in the message table 111 of the storage unit 110. According to the preferred embodiment, the message code content reading unit 122 compares the read message code read by the message code reading unit 121 with message codes stored in the message table 111. If the read message code does not match with a message code stored in the message table 111 currently being compared, the message code content reading unit 122 calculates an initial storage address of the next message code stored in the message table 111 according to a storage address for the message code and storage capacity information corresponding to the message code. The reading unit 122 then jumps directly to the initial storage address of the next message code stored in the message table 111, and fetches and compares the next message code with the read message code. This process continues until a message code stored in the message table 111 is found to match with the read message code. Finally, the host module 120 has the control unit 123 display the message code read by the message code reading unit 121 and the message code message read by the message code content reading unit 122, such display appearing on the display unit 30 of the electronic device 1. Therefore, a user of the electronic device 1 can immediately know the operational status at every stage of the POST process, and can perform debugging according to the message code messages if the electronic device 1 encounters a problem when executing the POST process.

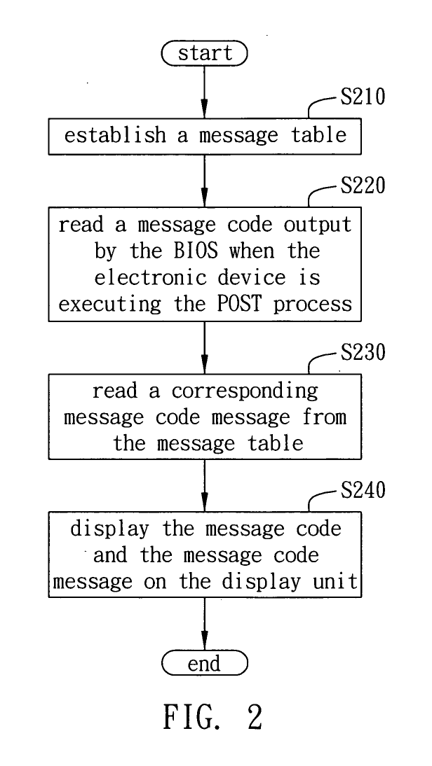

FIG. 2 is a flow chart of a message displaying method corresponding to the message displaying system 10. The message display method is applicable to the electronic device 1, which has the BIOS 20 and the display unit 30, and is executing the POST process.

The message displaying method starts in step S210. In step S210, the message table 111 is established. The message table 111 comprises a plurality of message codes output by the BIOS 20 when the electronic device 1 is executing the POST process, a plurality of message code messages corresponding to the message codes, and storage capacity information for the message codes and the message code messages. According to the preferred embodiment, the message codes correspond to POST codes. The method then proceeds to step S220.

In step S220, a message code output by the BIOS 20 is read when the electronic device 1 is executing the POST process. The method then proceeds to step S230.

In step S230, the message code message corresponding to the read message code is read from the message table 111. In practice, the read message code is compared with one of the message codes stored in the message table 111. If the read message code does not match the message code stored in the message table 111, the initial storage address of the next message code is calculated according to the storage address of the message code and the storage capacity information corresponding to the message code, and the next message code stored in the message table 111 is fetched and compared with the read message code, this process continuing until one of the message codes stored in the message table 111 is found to match the read message code. Further, the corresponding message code message is read from the message table 111. Proceed to step S240.

In step S240, the read message code and its corresponding message code message are displayed on the display unit 30 of the electronic device 1. Thereby, a user of the electronic device 1 can know the status at every stage of the POST process, and can perform debugging according to the message code message if the electronic device 1 encounters a problem when executing the POST process.

In summary, the message displaying system and method of the present invention first stores a plurality of message codes output by the BIOS when the electronic device is executing the POST process and a message table having a plurality of message code messages corresponding to the message codes into the storage unit, then the host module reads the message codes output by the BIOS when the electronic device is executing the POST process and the corresponding message code messages from message table according to the read message code, and, lastly, displays the read message codes and corresponding message code messages on the display unit. Thereby, a user of the electronic device 1 is can know the status at every stage of the POST process, and can perform debugging according to the message code messages if the electronic device 1 encounters any problems when executing the POST process. Moreover, the message displaying system and method cost less since they do not require installation of any additional hardware.

The foregoing descriptions of the detailed embodiments are only illustrated to disclose the features and functions of the present invention and are not restrictive on the scope of the present invention. It should be understood to those in the art that various modifications and variations can be made with departing from the spirit and principle of the disclosure of the present invention as described in the appended claims.

What is claimed is:

1. A message displaying system applicable to an electronic device having a basic input/output system (BIOS) and a display unit, wherein the electronic device executes a power-on self test (POST) process, the message displaying system comprising:
a storage unit for storing a plurality of message codes output by the BIOS when the electronic device is executing the POST process, and a message table comprising a plurality of message code messages corresponding to the message codes; and
a host module for reading message codes output by the BIOS when the electronic device is executing the POST process, reading the message code messages stored in the message table of the storage unit and corresponding to the read message codes, and displaying the read message codes and the message code messages on the display unit of the electronic device.

2. The message displaying system of claim 1, wherein the storage unit is a memory.

3. The message displaying system of claim 1, wherein the message codes are POST codes.

4. The message displaying system of claim 1, wherein the message table further comprises storage capacity information for the message codes and their corresponding message code messages to facilitate more efficient processing.

5. The message displaying system of claim 1, wherein the host module comprises:
a message code reading unit for reading message codes output from the BIOS when the electronic device is executing the POST process;
a message code content reading unit for reading the message code messages stored in the message table of the storage unit corresponding to the read message codes read by the message code reading unit; and
a control unit for displaying the read message codes read by the message code reading unit and the message code messages read by the message code content reading unit on the display unit of the electronic device.

6. The message displaying system of claim 1, wherein the electronic device is selected from the group consisting of a desktop computer, a notebook computer, a pocket personal computer, a server, and a super computer.

7. The message displaying system of claim 1, wherein the display unit is a display.

8. A message displaying method applicable to an electronic device having a BIOS and a display unit, wherein the electronic device executes a POST process, the message displaying method comprising:
establishing a message table according to a plurality of message codes output by the BIOS when the electronic device is executing the POST process and a plurality of message code messages corresponding to the message codes;
reading message codes output by the BIOS when the electronic device is executing the POST process;
reading the message code messages stored in the message table corresponding to the read message codes; and
displaying the read message codes and corresponding message code messages on the display unit of the electronic device.

9. The message displaying method of claim 8, wherein the message table is stored in a storage unit.

10. The message displaying method of claim 9, wherein the storage unit is a memory.

11. The message displaying method of claim 8, wherein the message codes are POST codes.

12. The message displaying system of claim 8, wherein the message table further comprises storage capacity information for the message codes and their corresponding message code messages to facilitate more efficient processing.

13. The message displaying method of claim 8, wherein the electronic device is selected from the group consisting of a desktop computer, a notebook computer, a pocket personal computer, a server, and a super computer.

14. The message displaying method of claim 8, wherein the display unit is a display.
